(19) United States
(12) Patent Application Publication
(10) Pub. No.: US 2006/0176429 A1
(43) Pub. Date: Aug. 10, 2006

(54) Diffusing structure with UV absorbing properties

(75) Inventors: Marie-Isabelle Watchi, Paris (FR); Michele Schiavoni, Paris (FR); Franck Marandon, Paris (FR)

Correspondence Address: OBLON, SPIVAK, MCCLELLAND, MAIER & NEUSTADT, P.C., 1940 DUKE STREET, ALEXANDRIA, VA, 22314, US

(73) Assignee: SAINT-GOBAIN GLASS FRANCE, Courbevoie (FR)

(21) Appl. No.: 11/345,501

(22) Filed: Feb. 2, 2006

(30) Foreign Application Priority Data
Feb. 9, 2005 (FR) 0550381

(51) Int. Cl. G02F 1/1335

(52) U.S. Cl. 349/119

(57) ABSTRACT

Diffusing structure (20) that absorbs in the ultraviolet, comprising a glass substrate (21) and a diffusing layer (22), the diffusing layer comprising scattering particles dispersed in a binder, characterized in that the diffusing layer (22) comprises particles that absorb ultraviolet radiation in the 250 to 400 nm range, said absorbent particles being formed by oxides having ultraviolet absorption properties.

The present invention relates to a diffusing structure that is intended to make a light source uniform and also has absorption properties in the ultraviolet, in particular over the 250 to 400 nm range.

The invention will be more particularly described with reference to a diffusing structure used to make the light emitted by a backlighting system uniform.

A backlighting system, which consists of a light source or backlight, is for example used as a backlighting source for liquid-crystal displays, called LCDs. It is apparent that the light thus emitted by the backlighting system is not sufficiently uniform and exhibits excessively high contrasts. Diffusing means associated with the backlighting system are therefore necessary in order to make the light uniform.

The invention may also be employed when it is required to make the light coming from flat architectural lamps uniform, for example those used on ceilings, floors or walls. They may also be flat lamps for municipal usage, such as lamps for advertising panels, or else lamps that may constitute the shelves or backs of display windows.

These flat lamps may also find applications in other fields, such as for example, the automotive industry. This is because it is conceivable to produce motor-vehicle roofs in which at least one part includes such a lamp, in particular to replace the currently-known lighting for motor vehicle passenger compartments. It is also possible to produce the backlighting for the instrument panels of motor vehicles.

One satisfactory solution from the uniformity standpoint consists in covering the front face of the backlighting system with a sheet of plastic, such as a polycarbonate or acrylic polymer (for example PMMA) filled with mineral fillers, the sheet having for example a thickness of 2 mm.

However, since this plastic is heat sensitive, it will age poorly and the heat given off will generally result in structural deformation of the plastic diffusing means, specifically leading to non-uniformity in the luminance of the projected image, for example at the LCD display.

Moreover, it is sometimes useful, depending on the use to which the backlighting system is put, to combine with the diffusing means, on the observer's side one or more optical filters, such as a device for redirecting the light output by the diffusing means of the BEF® film type and/or a reflective polarizer of the DBEF® type, allowing one polarization of the light to be transmitted and the orthogonal polarization to be reflected. The light source or sources used in the backlighting system are, for example, lamps or discharge tubes commonly called CCFLs (cold cathode fluorescent lamps), HCFLs (hot cathode fluorescent lamps) and DBDFLs (dielectric barrier discharge fluorescent lamps), or else lamps of the LED (light-emitting diode) type. However, ultraviolet radiation, in particular in the 250 to 400 nm wavelength range, produced by such light sources reaches these optical filters, which, over the course of time ends up by damaging them.

To cut the transmission of this ultraviolet radiation, it is known to give the diffusing plastic sheet the function of an ultraviolet filter. However, these plastic diffusing means end up by yellowing over the course of time, thereby degrading the final light emitted.

Another solution has been proposed in International Patent Application PCT/FR04/001717, which consists in using a diffusing structure comprising a glass substrate having properties tailored to diffusion, in particular such as the substrate described in the International Patent Application published under the number WO 01/90787, which is combined with an ultraviolet-filtering plastic film.

Thus, the diffusing structure comprises a glass substrate on which a diffusing layer has been deposited, and a plastic film such as PVB that can absorb the wavelengths in the ultraviolet range and is fastened to the glass substrate, on the opposite side from the diffusing layer.

The diffusing layer in that document consists of particles dispersed in a binder, said particles having a mean diameter of between 0.3 and 2 microns and consisting of nitrides, carbides or oxides chosen, for example from silicon, aluminium, zirconium, titanium and cerium oxides, or of a mixture of at least two of these oxides.

Although this solution of combining an ultraviolet-filtering film with a glass diffusing structure is very satisfactory from the standpoint of optical quality, and also the standpoint of durability of the assembly, it does require an additional assembly process for joining the filtering film to the diffusing structure. This entails additional processing means and higher manufacturing costs.

It is therefore the object of the invention to provide a diffusing structure that cuts off the ultraviolet radiation, in particular within the 250 to 400 wavelength range, while still being sufficiently transparent to visible light and the manufacture of which does not entail processing complexities and high production and operating costs.

According to the invention, the diffusing structure that absorbs in the ultraviolet, comprises a glass substrate and a diffusing layer, the diffusing layer comprising, dispersed within a binder, scattering particles that consist of nitrides, carbides or oxides, the oxides being chosen from silica, alumina, zirconia, titania, and ceria, or being a mixture of at least two of these oxides, and is characterized in that the diffusing layer comprises particles that absorb ultraviolet radiation in the 250 to 400 nm range, the said absorbent particles being formed from oxides having ultraviolet absorption properties.

The term “scattering particles” is understood to mean particles of which the nature of the material and the volume thereof make it possible to transmit the wavelengths in the visible range, while still diffusing the light.

According to one feature, the absorbent particles are chosen from one of the following oxides or a mixture thereof: titanium oxide, vanadium oxide, cerium oxide, zinc oxide and manganese oxide.

Advantageously, the absorbent particles have a mean diameter of at most 2 μm.

The absorbent particles represent 1 to 8% or even 1 to 20% of the weight of the mixture of binder, scattering particles and absorbent particles.

According to another feature, the structure has a transmission ratio T₃₆₅/T₄₅₀ of less than 60%, where T₃₆₅ and T₄₅₀ are the transmission for radiation at 365 nm and at 450 nm, respectively, and/or a transmission ratio T₃₁₅/T₄₅₀ of less than 30%, where T₃₁₅ and T₄₅₀ is the transmission for radiation at 315 nm and at 450 nm, respectively.

Advantageously, the scattering particles have a mean diameter of between 0.3 and 2 μm and consist of mineral particles, such as oxides, nitrides or carbides.

The binder is chosen from mineral binders, such as potassium silicates, sodium silicates, lithium silicates, aluminium phosphates and glass frits.

According to one embodiment of the diffusing layer that absorbs radiation from 250 to 400 nm, the layer comprises a glass frit as binder, alumina as scattering particles and titanium oxide as absorbent particles in proportions of 1 to 8% by weight of the mixture, the absorbent particles having a mean diameter of at most 0.1 μm.

Finally, the invention relates to the use of a diffusing structure facing a light source in order to diffuse the light emitted by this light source, the diffusing structure having a glass substrate and a diffusing layer formed from scattering particles dispersed in a binder, characterized in that the diffusing layer also constitutes means for absorbing radiation of wavelengths lying within the 250 to 400 nm range.

In such a use, the diffusing structure has the features as described above as regards a diffusing and ultraviolet-absorbent structure according to the invention. In particular, the diffusing layer comprises particles that absorb ultraviolet radiation in the 250 to 400 nm range and formed from oxides having ultraviolet absorption properties.

The diffusing structure of the invention would advantageously be used in a backlighting system that can be placed in an LCD-type display or in a flat lamp or else in a projection device.

Other advantages and features of the invention will become apparent from the rest of the description with regard to the appended drawings, in which:

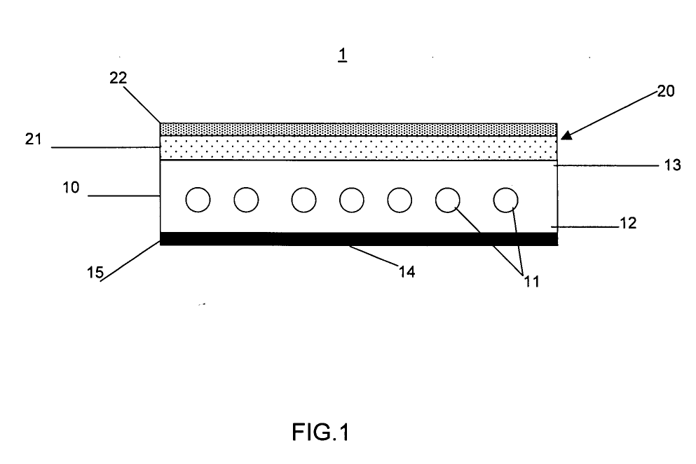

FIG. 1 illustrates a backlighting system according to the invention; and

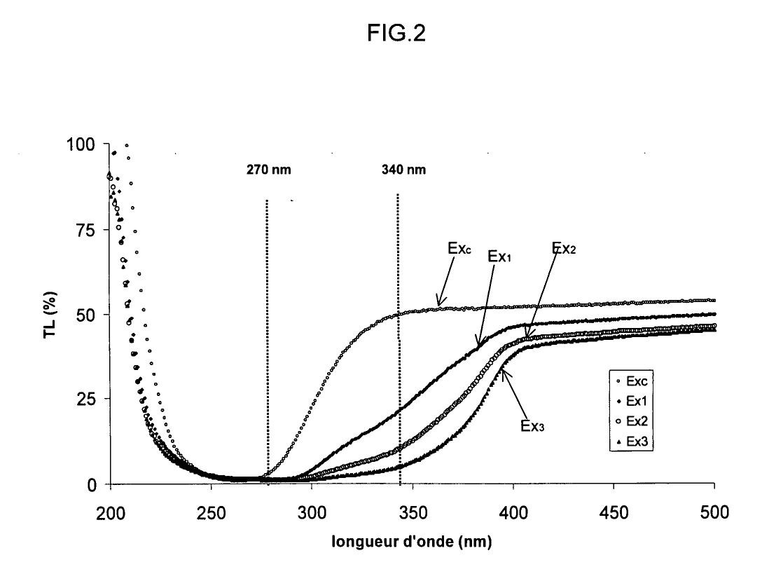

FIG. 2 illustrates comparative ultraviolet transmission curves for examples of a backlighting system.

For the sake of clarity, in FIG. 1, the dimensions of the various elements have not been drawn to scale.

FIG. 1 illustrates a backlighting system 1 intended for example to be used in an LCD display. The system 1 comprises an enclosure 10, containing an illuminant or light sources 11, and a glass diffusing structure 20 joined to the enclosure 10.

The enclosure 10, with a thickness of about 10 nm, has a lower part 12 in which the light sources 11 are placed, and on the opposite side, an upper part 13 that is open, through which the light emitted by the sources 11 propagates. The lower part 12 has a bottom 14 against which reflectors 15 are placed, these being intended to reflect, on the one hand, that part of the light emitted by the sources 11 which is directed towards the lower part 12 and, on the other hand, that part of the light which is not transmitted through the diffusing substrate but reflected by the glass substrate and backscattered by the diffusing layer.

The light sources 11 are for example discharge tubes of the CCFL type.

The diffusing structure 20 is fitted on to the upper part 13 and firmly held in place by mechanical means (not shown) such as clip-fastening means that cooperate with the enclosure and the structure, or else held in place by mutual engagement means (not illustrated) such as a groove provided around the periphery of the surface of the structure that cooperates with a peripheral rib on the enclosure.

The diffusing structure 20 comprises a glass substrate 21, for example with a thickness of 2 mm, and a diffusing layer 22 with a thickness of between 3 and 20 μm and placed on one face of the glass substrate, on the same side as or on the opposite side from the upper part 13 of the enclosure.

The substrate 21 for supporting the layer is made of transparent glass. This glass may advantageously be extra clear, that is to say it may have a low light absorption so that its light transmission TL under illuminant D₆₅ is at least equal to 90.5%, for a glass thickness of 3 mm. Such an example is the glass DIAMANT from Saint Gobain or the glass B270 from Schott.

The diffusing layer 22 comprises a binder and scattering particles, the nature of the material of the particles and their volume making it possible to transmit wavelengths in the visible range, while still scattering the light.

The scattering particles are preferably mineral particles such as oxides, nitrides or carbides. Among oxides, the choice may be directed towards silica, alumina, zirconia, titania or ceria, or a mixture of at least two of these oxides.

The particles have a mean diameter of between 0.3 and 2 μm.

The binder is chosen from mineral binders such as potassium silicates, sodium silicates, lithium silicates, aluminium phosphates and glass frits.

To provide the ultraviolet absorption function, in particular in the 250 to 400 nm range, included in the diffusing layer 22 are oxide particles having ultraviolet absorption properties such as titanium, vanadium, cerium, zinc or manganese oxides, or a mixture of these oxides.

These absorbent particles have a diameter of at most 2 μm.

The absorbent particles may also consist entirely or partly of the scattering particles when these are oxides. Thus, they fulfil the role of both absorbent particles and scattering particles.

The proportions of the binder and the scattering and absorbent particles are adapted according to the desired light transmission and the desired diffusing power, and also the expected ultraviolet cut-off performance.

The index of the scattering particles and of the absorbent particles is advantageously greater than 1.7, while that of the binder is preferably less than 1.6. The ultraviolet-absorbent diffusing layer 22 is deposited by any technique known to those skilled in the art, such as by screen printing, brush coating, dip coating, spin coating, spraying or flow coating.

Given below are three examples of an ultraviolet absorbent diffusing layer according to the invention which has, once deposited on the glass substrate, a thickness of 4 μm, the glass substrate having a thickness of 2 mm and the composition of the glass corresponding to the glass B270 from Schott.

Each example is formed from a mixture of binder (product VN821BJ sold by Ferro), scattering particles (CR1-type alumina sold by Baikowski) and absorbent particles (TiO₂ particles 30 nm in diameter, sold by Rossow).

Table I below gives, for each of the examples (with the references Ex₁, Ex₂, and Ex₃), the percentages by weight of the components of the mixture forming the deposited layer.

TABLE I

| | Ex₁ | Ex₂ | Ex₃ |
|---|---|---|---|
| Binder | 49% | 48% | 46% |
| Scattering | 50% | 50% | 50% |
| particles | | | |
| Absorbent | 1% | 2% | 4% |
| particles | | | |

The glass substrate 21 is thus used as a support for the diffusing layer 22, so as to constitute the ultraviolet-absorbent diffusing structure 20 that is combined with the enclosure 10 to form the backlighting system 1.

Measurements of the ultraviolet absorption over the 200 to 400 nm range of the diffusing structure 20 were made when the illumination provided by the system 1 consisting of CCFL tubes passes through it, no optical device being combined with the diffusing structure.

The absorption performance, in particular over the 315 to 400 nm range, was found to increase with the increase in content of absorbent particles for examples Ex₁ to Ex₃ compared with this absorption for a diffusing structure containing no absorbent particles. The comparative example, denoted Exc, consists of 50% binder and 50% alumina scattering particles of the above examples. It provides no absorption function for radiation over this wavelength range.

Table II below summarizes these measurements, giving the average transmission for radiation over the 315 to 400 nm range, the measurements having been made using a detector placed perpendicular to the surface of the structure, in particular with a photoradiometer of the “Delta OHM HD 9021/UVA” type.

TABLE II

| | |
|---|---|
| EX_{c} | 100% |
| Ex₁ | 63% |
| Ex₂ | 46% |
| Ex₃ | 33% |

FIG. 2 illustrates ultraviolet radiation transmission curves for the examples Ex₁, Ex₂, and Ex₃ and for the comparative example Exc.

This clearly shows that, for between 270 and 400 nm, the diffusing structure containing no ultraviolet absorbing particles (Exc) lets through a significant amount of the ultraviolet radiation, with a transmission of 20% at 300 nm, whereas the diffusing structures containing absorbent particles (Ex₁ to Ex₃) do not let through the 300 nm radiation and that the transmission in the case of comparative example Exc reaches 50% at 340 nm, whereas the other examples Ex₁ to Ex₃ have, for this 340 nm wavelength, a transmission that does not even reach 20% in the case of Ex₁, and not even 10% in the case of Ex₂ and Ex₃.

Finally, it has been demonstrated that the addition of absorbent particles does not degrade the transmission in the visible range. In particular, the luminance of the illumination coming from the enclosure and passing through the diffusing structure containing absorbent particles (examples Ex₁ to Ex₃) has a luminance that admittedly is lower than that of a diffusing structure containing no absorbent particles (example ExC), but when the diffusing structure is combined with an optical device, which is generally the case in the use to which the backlighting system 1 is put, the luminance is hardly affected by the presence of absorbent particles.

Table III below thus gives the performance characteristics obtained as regards the mean luminance for backlighting systems incorporating the diffusing structures of examples Ex₁ to Ex₃ and example Exc with and without an optical device. The luminance was measured perpendicular to the surface of the diffusing structure by means of a Minolta LS-110 luminance meter.

TABLE III

| | Luminance | |
|---|---|---|
| | performance | Luminance |
| | without an optical | performance |
| | device | with an optical device |
| EX_{c} | 100% | 100% |
| Ex₁ | 98% | 99% |
| Ex₂ | 96% | 98.5% |
| Ex₃ | 95% | 97.5% |

Finally, it should be noted that the glass substrate 21 may serve as a support for the deposition of coatings consisting of functional layers, such as an electromagnetic screening coating, which may also constitute the diffusing layer 22, as described in French Patent Application FR 02/08289, a coating with a low-emissivity function, an antistatic, antifogging or antifouling function or else a luminance-enhancing function. The latter function may really be desirable for application of the diffusing substrate in an LCD display.

1. Diffusing structure (20) that absorbs in the ultraviolet, comprising a glass substrate (21) and a diffusing layer (22), the diffusing layer comprising, dispersed within a binder, scattering particles that consist of nitrides, carbides or oxides, the oxides being chosen from silica, alumina, zirconia, titania, and ceria, or being a mixture of at least two of these oxides, characterized in that the diffusing layer (22) comprises particles that absorb ultraviolet radiation in the 250 to 400 nm range, the said absorbent particles being formed from oxides having ultraviolet absorption properties.

2. Diffusing structure according to claim 1, characterized in that the absorbent particles are chosen from one of the following oxides or a mixture thereof: titanium oxide, vanadium oxide, cerium oxide, zinc oxide and manganese oxide.

3. Diffusing structure according to claim 1 or 2, characterized in that the absorbent particles have a mean diameter of at most 2μm.

4. Diffusing structure according to any one of the preceding claims, characterized in that the absorbent particles represent 1 to 8%, or even 1 to 20%, of the weight of the mixture of binder, scattering particles and absorbent particles.

5. Diffusing structure according to any one of the preceding claims, characterized in that it has a transmission ratio T₃₆₅/T₄₅₀ of less than 60%, where T₃₆₅ and T₄₅₀ is the transmission for radiation at 365 nm and at 450 nm, respectively.

6. Diffusing structure according to any one of the preceding claims, characterized in that it has a transmission ratio T₃₁₅/T₄₅₀ of less than 30%, where T₃₁₅ and T₄₅₀ is the transmission for radiation at 315 nm and at 450 nm, respectively.

7. Diffusing structure according to any one of the preceding claims, characterized in that the scattering particles have a mean diameter of between 0.3 and 2 μm and consist of mineral particles, such as oxides, nitrides or carbides.

8. Diffusing structure according to any one of the preceding claims, characterized in that the binder is chosen from mineral binders, such as potassium silicates, sodium silicates, lithium silicates, aluminium phosphates and glass frits.

9. Diffusing structure according to any one of the preceding claims, characterized in that the layer (22) comprises a glass frit as binder, alumina as scattering particles and titanium oxide as absorbent particles in proportions of 1 to 8% by weight of the mixture, the absorbent particles having a mean diameter of at most 0.1 μm.

10. Use of a diffusing structure according to one of claims 1 to 9, the diffusing structure facing a light source in order to diffuse the light emitted by this light source, and having a glass substrate and a diffusing layer formed from scattering particles dispersed in a binder, characterized in that the diffusing layer also constitutes means for absorbing radiation of wavelengths lying within the 250 to 400 nm range.

11. Use according to claim 10, characterized in that the diffusing layer comprises particles that absorb ultraviolet radiation in the 250 to 400 nm range and consist of oxides having ultraviolet absorption properties.

12. Use of a diffusing structure according to any one of the preceding claims for producing a backlighting system.

13. Use according to claim 12, for which the backlighting system is placed in a display of the LCD type, in a flat lamp or in a projection device.
